(19) United States
(12) Patent Application Publication
(10) Pub. No.: US 2004/0063001 A1
(43) Pub. Date: Apr. 1, 2004

(54) Method of making an integrated circuit using a photomask having a dual antireflective coating

(76) Inventors: Wei E. Wu, Austin, TX (US); Sergei V. Postnikov, Austin, TX (US)

Correspondence Address: MOTOROLA INC, AUSTIN INTELLECTUAL PROPERTY, LAW SECTION, 7700 WEST PARMER LANE MD: TX32/PL02, AUSTIN, TX, 78729

(21) Appl. No.: 10/260,318

(22) Filed: Sep. 30, 2002

(51) Int. Cl. G03F 1/00; G03F 7/20; G03F 7/40

(52) U.S. Cl. 430/5; 430/311; 430/950; 430/317

(57) ABSTRACT

A wafer (18) is made using a mask (14) that has a quartz substrate (15) and a patterned stack (32) for providing a mask pattern. The patterned stack comprises an opaque layer (36) between two ARC layers (34, 38). The patterned stack reduces flare, which in turn improves critical dimension (CD) control. The stack reduces the reflections that come from the interface between the opaque layer (36) and quartz substrate (15). This stack also absorbs the reflections that come back from the direction of the wafer. The opaque layer (36) is silicon, which is opaque at wavelengths below 300 nanometers, and the ARC layers are non-stoichiometric silicon nitride.

### FIELD OF THE INVENTION

This invention relates generally to semiconductor circuits, and more specifically, to the manufacture of semiconductor circuits.

### BACKGROUND OF THE INVENTION

Physical limitations associated with lithography that is used to fabricate semiconductor devices are an issue for small dimensions. In optical lithography, a photosensitive film, a photoresist, is patterned by a photomask. A photoresist is formed onto a wafer having integrated circuits. The photomask has areas composed of a light absorber in a feature that corresponds to the desired circuitry for the integrated circuits. Portions of the photoresist as determined by the photomask are exposed to light from a light source. After exposure, a desired device pattern remains in the photoresist on the wafer. Further processing may be performed to transfer the resulting photoresist pattern onto the wafer.

However, in exposing the photoresist to the light source, openings in the photomask do not exactly transfer to the wafer as a result of light diffraction and reflection. A condition known as flare occurs when light is radiated onto areas of the wafer that should not be exposed to light. Flare caused by light being reflected from optical components degrades optical microlithography perfomance. The photomask is considered one of the optical components. A conventional photomask uses a quartz plate with an overlying absorber material, such as chromium. The chromium is used to form the desired features for the integrated circuit. The reflectivity from quartz and chromium is about forty percent that adds about two percent extra flare through the system. Elimination or reduction of such reflection is needed.

### BRIEF DESCRIPTION OF THE DRAWINGS

The present invention is illustrated by way of example and is not limited by the accompanying figures, in which like references indicate similar elements.

FIG. 1 illustrates a photolithographic system having a photomask in accordance with the present invention;

FIG. 2 illustrates in further detail the photomask for use in the system of FIG. 1; and

FIG. 3 illustrates in flow chart form a lithographic process of patterning the photomask of FIG. 2 in a process of making an integrated circuit.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION

FIG. 1 illustrates a lithographic system 10 generally having a light source 12, a photomask 14 including a quartz plate 15. The light source 12 selectively transmits light to optics 16 through the photomask 14. The optics 16 focuses the light onto a photoresist on the surface of a wafer 18. The open area of photomask 14 exposes areas 20, 22 and 24 of the photoresist on the wafer 18 with light. Areas 26 and 28 of the photoresist are not exposed to light because the light was blocked by the absorbing stacks 30 and 32 of photomask 14. Each of absorbing stacks 30 and 32 has three layers of material and functions as a patterned opaque stack to form a mask pattern. For example, absorbing stack 32 has a first antireflective coating (ARC) 38, an opaque layer 36 and a second antireflective coating (ARC) 34. Opaque layer 36 functions to block all or nearly all light (e.g. ninety-nine percent), but in any event blocks at least eighty percent of the light. In one form, opaque layer 36 may be implemented with substantially pure silicon (including polysilicon). The term “substantially pure silicon” includes doped silicon, but not silicon-containing compounds. Alternative materials may include metal, silicides and other non-transparent materials. The first ARC 38 and the second ARC 34 may be implemented respectively by non-stoichiometric silicon nitride. Alternative ARC materials may include any transparent dielectric materials, such as SiOₓN_{y}, CaF₂, MgF₂, although not limited to these materials, to form a dielectric layer.

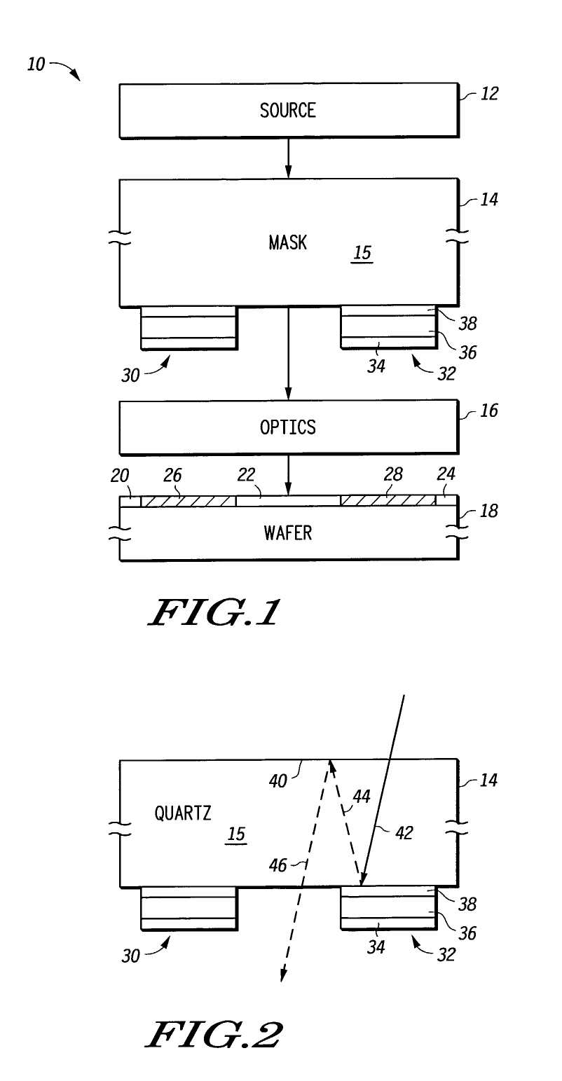

Illustrated in FIG. 2 is a detail of the absorbing stacks 30 and 32 of photomask 14. For convenience of illustration, elements that are common in FIG. 1 and FIG. 2 are provided with the same figure reference number. Assume initially that the mask 14 does not have an ARC layer such as ARC 38 in the absorbing stack 32 in any of the absorbing stacks. Further assume that incoming light 42 is not collimated and therefore not exactly perpendicular to the interface of quartz plate 15 and the absorbing stack 32. As a result, the light 42 is reflected from the interface as represented by reflected light 44. The reflected light 44 is then reflected from an upper surface 40 of quartz plate 15. A reflected light 46 is then radiated through the pattern opening between absorbing stacks 30 and 32. This light is passed through optics 16. Because the reflected light 46 is directed to optics 16 at an angle other than ninety degrees, the light 46 will undesirably expose a portion of either area 26 or area 28, or both. This undesired exposure is characterized as flare.

Assume now that the structure of absorbing stacks 30 and 32 as illustrated in FIG. 2 exists. When light 42 strikes the interface of quartz plate 15 and the absorbing stack 32, the light is not reflected as reflected light 44. Instead, ARC 38 passes substantially all the light through instead of reflecting the light. When the light reaches the opaque layer 36, the light will be absorbed. Therefore, the absorbing stacks 30 and 32 efficiently function to avoid the previously noted flare.

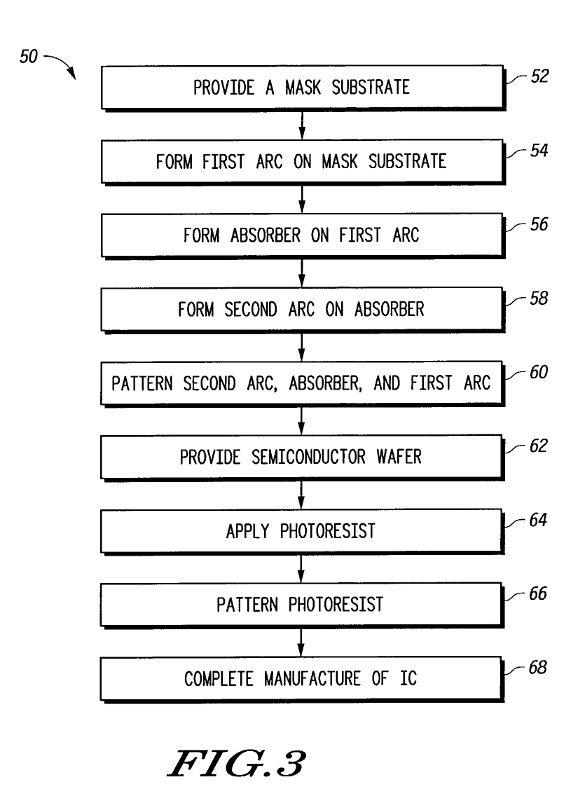

Illustrated in FIG. 3 is a flowchart of a process 50 for patterning a photomask to make an integrated circuit on a wafer. In a step 52, a mask substrate, such as quartz plate 15, is provided. A first ARC, such as ARC 38, is formed on the mask substrate in a step 54. An absorber, such as absorber 36, is formed on the first ARC in a step 56. A second ARC, such as ARC 34, is formed on the absorber in a step 58. The first ARC, absorber and second ARC is patterned pursuant to a desired integrated circuit pattern to form a mask in a step 60. A semiconductor wafer, such as silicon wafer 18, is provided in a step 62. Photoresist is applied to the silicon wafer 18 in a step 64 to form a photoresist layer. In a step 66, the photoresist is patterned using the mask from the step 60. In a step 68, semiconductor processes are performed on the wafer 18 to complete manufacture of an integrated circuit.

It should be noted that when absorbing stacks 30 and 32 are implemented using SiNₓ, silicon and SiN_{y}, the absorbing stacks are easily etched using a dry or plasma etching process. Such processes are very selective, have excellent resolution at small dimensions and have low cost. The use of silicon for the absorbing stacks also has the advantage of being a low stress structure due to silicon having a low coefficient of thermal expansion that minimizes stress fractures and peeling of small features from the mask. The implementation of silicon nitride ARCs reduces flares that permits improved control of the critical dimensions of the features.

The determination of the composition of silicon nitride, SiNₓ and SiN_{y}, may be optimized to minimize reflection. Depending on the wavelength of the light source 12, the amount of reflection can be calculated as a function of both the extinction coefficient, k, of the silicon nitride and the thickness of the silicon nitride. Thus, a contour is generated that details an optimal silicon nitride thickness and extinction coefficient that results in minimal reflectivity characteristic. From this contour information, plots can be readily generated that illustrate a plot of how the reflectivity percentage of silicon nitride varies with respect to the extinction coefficient for various light wavelengths. Similarly, plots can be readily generated that illustrate how the reflectivity of silicon nitride varies with respect to the thickness of the silicon nitride film. The optimum value is then used to determine values of x and y for the silicon nitride composition.

It should be noted that x and y may be the same value, but the first ARC layer may have a first non-stoichiometric composition and the second ARC layer may have a second non-stoichiometric composition that is different from the first non-stoichiometric composition.

By now it should be appreciated that there has been provided a photolithographic system for use in making an integrated circuit wherein flare caused by light reflection from a photomask is minimized. In the illustrated form, first and second distinct ARC layers are used on a same side of a quartz plate. Between the first and second ARC layers is an absorbing layer. Although various absorbing layer materials may be used, Applicants have discovered that the use of silicon for the absorbing layer has numerous advantages over prior metals that have been used, such as chromium. Preferably, the absorbing layer has an extinction coefficient of at least one. For example, silicon has higher absorption than chromium in short wavelengths, such as below 300 nm. The use of silicon results in improved critical dimension control, better resolution and more stability in the photomask structure.

In the foregoing specification, the invention has been described with reference to specific embodiments. However, one of ordinary skill in the art appreciates that various modifications and changes can be made without departing from the scope of the present invention as set forth in the claims below. For example, various compositions of silicon nitride may be used for each of the ARC layers in the absorbing stacks 30 and 32. Semiconductor wafers other than silicon-based wafers may be manufactured using the disclosed photolithography system. Various types of optics may be used to implement optics 16. Various optical materials in addition to quartz plate 15 may be used for mask 14. Differing types of light may be used as the light source 12. Examples of the light source 12 include argon fluoride, krypton fluoride and fluoride lasers. Various wavelength light may be used; however the wavelength should not be greater than about 300 nanometers. Accordingly, the specification and figures are to be regarded in an illustrative rather than a restrictive sense, and all such modifications are intended to be included within the scope of the present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. The terms a or an, as used herein, are defined as one or more than one. The term plurality, as used herein, is defined as two or more than two. The term another, as used herein, is defined as at least a second or more. The terms including and/or having, as used herein, are defined as comprising (i.e., open language). The term coupled, as used herein, is defined as connected, although not necessarily directly, and not necessarily mechanically.

1. A method of making an integrated circuit, comprising:
providing a mask substrate;
forming a first anti-reflective coating (ARC) adjacent to the mask substrate;
forming an absorbing layer adjacent to the first ARC;
forming a second anti-reflective coating (ARC) adjacent to the absorbing layer;
patterning the second ARC, the absorbing layer, and the first ARC to form a mask pattern;
providing a semiconductor wafer;
forming a photoresist layer over the semiconductor wafer;
exposing the photoresist layer according to the mask pattern; and
performing semiconductor processes on the semiconductor wafer to complete the integrated circuit.

2. The method of claim 1, wherein the first ARC layer comprises silicon nitride, the absorbing layer comprises silicon, and the second ARC layer comprises silicon nitride.

3. The method of claim 2, wherein the first ARC layer is on the mask substrate, the absorbing layer is on the first ARC layer, and the second ARC layer is on the absorbing layer.

4. The method of claim 3, wherein the photoresist layer is exposed by light with a wavelength not greater than about 300 nanometers.

5. The method of claim 3, wherein the first ARC layer has a first non-stoichiometric composition and the second ARC layer has a second non-stoichiometric composition different than the first non-stoichiometric composition.

6. The method of claim 1, wherein the first ARC layer is transparent, the second ARC layer is transparent, and the absorbing layer is opaque at wavelengths less than 300 nanometers.

7. The method of claim 6, wherein the first ARC layer and the second ARC layer are dielectric layers.

8. The method of claim 7, wherein the absorbing layer has an extinction coefficient of at least one.

9. A method of making an integrated circuit, comprising:
providing a mask substrate;
forming a first non-stoichiometric silicon nitride layer coupled to the mask substrate;
forming a silicon layer coupled to the first non-stoichiometric silicon nitride layer;
forming a second non-stoichiometric silicon nitride layer coupled to the substantially pure silicon layer;
forming a mask having a pattern using the mask substrate, the first and second non-stoichiometric silicon nitride layers, and the substantially pure silicon layer;
providing a semiconductor wafer;
forming a photoresist layer over the semiconductor wafer;
applying light to the mask aligned to the semiconductor wafer to expose the photoresist layer according to the pattern, wherein the light has a wavelength at which silicon is opaque; and
performing semiconductor processes on the semiconductor wafer to complete the integrated circuit.

10. A method of making an integrated circuit, comprising:
providing a mask substrate;
providing a mask having a pattern, wherein the mask comprises a patterned opaque stack coupled to the mask substrate, wherein the patterned opaque stack comprises a silicon layer between two layers of silicon nitride;
providing a semiconductor wafer;
forming a photoresist layer over the semiconductor wafer;
applying light to the mask aligned to the semiconductor wafer to expose the photoresist layer according to the pattern, wherein the light has a wavelength at which silicon is opaque; and
performing semiconductor processes on the semiconductor wafer to complete the integrated circuit.

11. The method of claim 10, wherein the two layers of silicon nitride are non-stoichiometric.

12. The method of claim 10, wherein the two layers of silicon nitride have non-stoichiometric compositions that differ from each other.

13. The method of claim 10, wherein the mask substrate is quartz.
